(19) United States
(12) Patent Application Publication
(10) Pub. No.: US 2021/0247243 A1
(43) Pub. Date: Aug. 12, 2021

(54) CIRCUIT BOARD ASSEMBLY

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventors: Shungo Hiratani, Yokkaichi-shi, Mie (JP); Hideaki Tahara, Yokkaichi-shi, Mie (JP); Arinobu Nakamura, Yokkaichi-shi, Mie (JP); Sanghee Chung, Yokkaichi-shi, Mie (JP)

(21) Appl. No.: 16/973,382

(22) PCT Filed: Jun. 19, 2019
(86) PCT No.: PCT/JP2019/024301

§ 371 Date: Dec. 8, 2020

(30) Foreign Application Priority Data
Jun. 26, 2018 (JP) 2018-121155

(51) Int. Cl. G01K 7/24; G01K 1/14; H05K 1/14; H05K 1/02

(52) U.S. Cl. CPC G01K 7/24; H05K 1/0212; H05K 1/14; G01K 1/14

(57) ABSTRACT

Provided is a circuit board assembly including an electronic component that generates heat, and a thermistor that is mounted on a circuit board that is spaced apart from the electronic component and that detects the temperature of the electronic component. The circuit board assembly further includes a heat conductive pattern formed surrounding the thermistor, and a heat conductive member that conducts heat from the electronic component to the heat conductive pattern.

### CROSS-REFERENCE TO RELATED APPLICATIONS

This application is the U.S. national stage of PCT/JP2019/024301 filed on Jun. 19, 2019, which claims priority of Japanese Patent Application No. JP 2018-121155 filed on Jun. 26, 2018, the contents of which are incorporated herein.

### TECHNICAL FIELD

The present disclosure relates to a circuit board assembly provided with a circuit board.

### BACKGROUND

Conventionally, circuit board assemblies are generally known in which conductive members (also called “bus bars”, for example) that form a circuit through which a relatively large current can flow is fixed to a circuit board with a conductive pattern that forms a circuit through which a relatively small current can flow.

On the other hand, WO 2016/042732A discloses a battery sensor apparatus in which a circuit board on which a thermistor is mounted is fixed to an attachment portion that is in contact with a terminal (heat source) of a battery and that detects heat of the battery.

In the circuit board assembly as described above, a large current flow makes the conductive members generate a lot of heat. By providing the circuit board spaced apart from the conductive members, the electronic components on the circuit board are prevented from being adversely affected by heat due to heating of the conductive members.

Furthermore, when a circuit involving the conductive members includes electronic components that generate heat and the temperature of the electronic components needs to be monitored, it is also necessary to provide a sensor and a control circuit that performs monitoring on the circuit board side to prevent the adverse effect by heat.

In this case, since the circuit board is provided spaced apart from the circuit involving the conductive members and thus heat generated by the electronic components is not readily conducted to the sensor side, and thus there is a problem in that it is difficult for the sensor to accurately detect the temperature.

However, in the battery sensor apparatus in WO 2016/042732A, since the circuit board on which the thermistor is mounted is directly fixed to the heat source via the attachment portion, heat from the heat source is conducted to the entirety of the circuit board via the attachment portion. Accordingly, if the control circuit and the like are mounted to the circuit board, they are adversely affected by heat. Accordingly, the battery sensor device in WO 2016/042732A cannot solve the above-described problem.

In view of this, an object of the present disclosure is to provide a circuit board assembly that includes electronic components that generate heat and a sensor that is mounted to the circuit board spaced apart from the electronic components and detects the temperature of the electronic components, with which the sensor can accurately detect heat (temperature) of the electronic components.

### Advantageous Effects of Disclosure

According to an aspect of the present disclosure, even when the sensor that is mounted on the circuit board detects heat (temperature) of the electronic components that are provided spaced apart from the circuit board, it is possible to detect heat of the components more accurately.

### SUMMARY

A circuit board assembly according to an aspect of the present disclosure includes an electronic component that generates heat, a sensor that is mounted on a circuit board that is spaced apart from the electronic component, the sensor being configured to detect a temperature of the electronic component, a heat conductive pattern that is formed surrounding the sensor, and a heat conductive member that conducts heat from the electronic component to the heat conductive pattern.

### BRIEF DESCRIPTION OF DRAWINGS

FIG. 1 is a front view of an electric apparatus according to a first embodiment.

FIG. 2 is an exploded view of the electric apparatus according to the first embodiment.

FIG. 3 is a schematic view of a circuit board assembly of the electric apparatus according to the first embodiment seen from below.

FIG. 4 is a vertical cross-sectional view taken along line IV-IV in FIG. 3.

FIG. 5 is an enlarged view showing a region of a heat conductive member in FIG. 4.

FIG. 6 is a partial schematic view of the circuit board of the circuit board assembly according to the first embodiment seen from above.

FIG. 7 is a vertical cross-sectional view showing a region of a thermistor in a circuit board assembly according to a second embodiment.

FIG. 8 is a partial schematic view of a circuit board of a circuit board assembly according to a third embodiment seen from above.

FIG. 9 is a vertical cross-sectional view showing a region of a thermistor in a circuit board assembly according to a fourth embodiment.

FIG. 10 is a vertical cross-sectional view showing a region of a thermistor in a circuit board assembly according to a fifth embodiment.

### DETAILED DESCRIPTION OF PREFERRED EMBODIMENTS

First, aspects of the present disclosure will be listed and described. At least some of the embodiments described below may also be combined as appropriate.

The circuit board assembly according to an aspect of the present disclosure includes an electronic component that generates heat, a sensor that is mounted on a circuit board that is spaced apart from the electronic component, the sensor being configured to detect a temperature of the electronic component, a heat conductive pattern that is formed surrounding the sensor, and a heat conductive member that conducts heat from the electronic component to the heat conductive pattern.

In this aspect, when the electronic component generates heat, the heat conductive member conducts the heat to the heat conductive pattern. Accordingly, the sensor surrounded by the heat conductive pattern can detect the temperature of the electronic component via the heat conductive pattern.

In the circuit board assembly according to an aspect of the present disclosure, another pattern may also be formed on the circuit board, and the heat conductive pattern may also be a land portion that is spaced apart from the other pattern.

In this aspect, since the heat conductive pattern is a land portion separate from the other pattern, it is possible to reduce cases in which heat of the heat conductive pattern is conducted to the other pattern. Accordingly, it is possible to prevent cases in which heat of the heat conductive pattern affects other electronic components via the other pattern.

In the circuit board assembly according to an aspect of the present disclosure, the heat conductive member may also include, on the circuit board side, a plurality of end portions that surround the sensor.

In this aspect, the heat conductive member includes a plurality of end portions, and the end portions surround the sensor. Accordingly, the heat from the electronic component that is conducted via the heat conductive member is readily conducted to the sensor, and thus the sensor can detect the temperature of the electronic component more accurately.

In the circuit board assembly according to an aspect of the present disclosure, a gap may also be present partially between the sensor and the circuit board, and a portion of the heat conductive pattern may also be formed in the gap.

In this aspect, since a portion of the heat conductive pattern is formed in the gap, heat is conducted to the sensor from the heat conductive pattern in the gap as well. Accordingly, the sensor can detect the temperature of the electronic component more accurately.

In the circuit board assembly according to an aspect of the present disclosure, the circuit board may also be constituted by a plurality of layers, and the circuit board may also include an internal heat conductive pattern formed in contact with the heat conductive member at a location corresponding to the sensor in a thickness direction of the circuit board in another layer than a layer on which the sensor is mounted.

In this aspect, since the internal heat conductive pattern is formed at a location of the circuit board that corresponds to the sensor in the thickness direction, heat is conducted to the sensor from the inside of the circuit board (internal heat conductive pattern) as well. Accordingly, the sensor can detect the temperature of the electronic component more accurately.

The circuit board assembly according to an aspect of the present disclosure may also include a conducting member that conducts heat of the heat conductive member to the sensor.

In this aspect, the conducting member directly conducts heat of the heat conductive member to the sensor. Accordingly, the sensor can detect the temperature of the electronic component more accurately.

Hereinafter, the present disclosure will be described in detail based on the drawings illustrating the embodiments thereof. The circuit board assembly according to the embodiments of the present disclosure will be described below with reference to the drawings. Note that the present disclosure is not limited to these illustrative examples and is defined by the claims, and all changes which come within the meaning and range of equivalency of the claims are intended to be embraced therein.

### First Embodiment

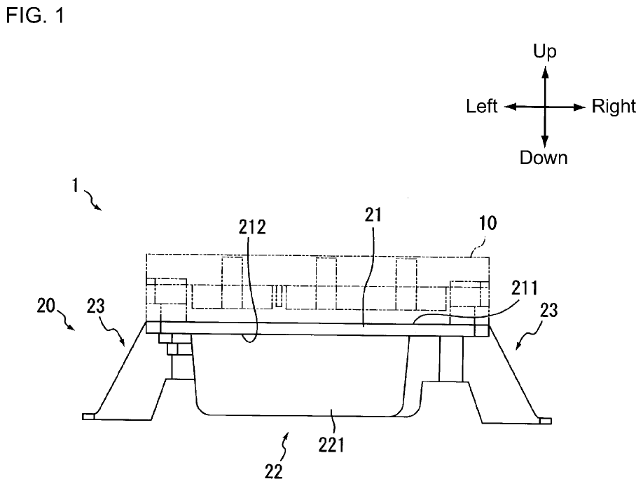

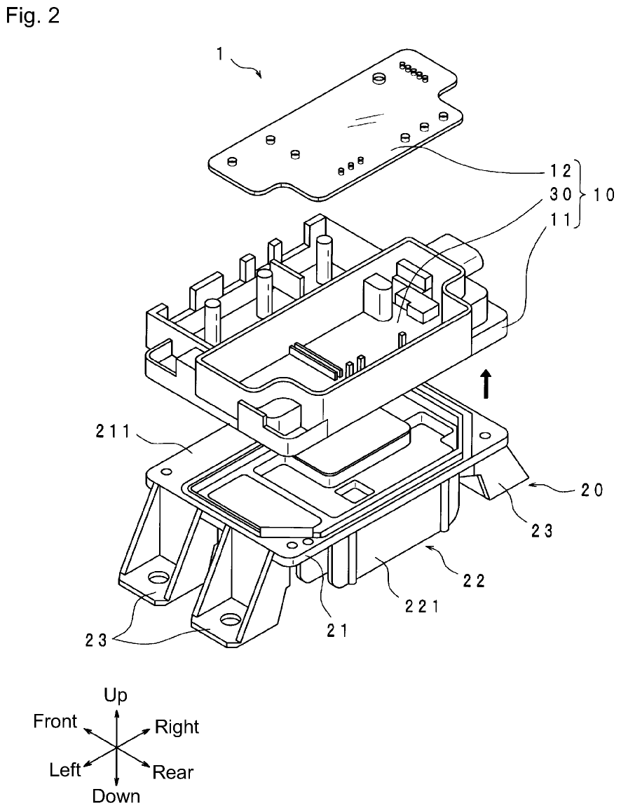

Hereinafter, a description will be given taking an electric apparatus including a circuit board assembly according to a first embodiment as an example. FIG. 1 is a front view of an electric apparatus 1 according to the first embodiment, and FIG. 2 is an exploded view of the electric apparatus 1 according to the first embodiment.

The electric apparatus 1 constitutes an electrical junction box that is arranged on a power supply path between a power supply such as a battery mounted in a vehicle and loads including in-vehicle electrical components such as a lamp and a wiper or a motor and the like. The electric apparatus 1 is used in an electric component such as a DC-DC converter or an inverter.

In the first embodiment, for illustrative reasons, “front”, “back”, “left”, “right”, “up”, and “down” of the electric apparatus 1 are defined according to the front-rear, left-right, and up-down directions shown in FIG. 1 and FIG. 2. Hereinafter, the structure of the electric apparatus 1 will be illustrated using the front, rear, left, right, up and down directions as defined above.

The electric apparatus 1 is provided with a circuit board assembly 10 and a support member 20 that supports the circuit board assembly 10. The circuit board assembly 10 is provided with a circuit board 12 that includes a circuit pattern, a bus bar constituting a power circuit, and electronic components and the like (not shown) that are mounted on the circuit board and the bus bar. The electronic components are mounted as appropriate in accordance with the usage of the electric apparatus 1, and include a switching element such as a FET (Field Effect Transistor), a resistor, a coil, a capacitor, and the like.

The support member 20 is provided with a base portion 21 that has a support surface 211 that supports the circuit board assembly 10 on the upper side, a heat dissipation portion 22 provided on a surface (lower side 212) that is opposite to the support surface 211, and a plurality of leg portions 23 provided at the left and right ends of the base portion 21 with the heat dissipation portion 22 interposed therebetween. The base portion 21, the heat dissipation portion 22, and the leg portions 23, that are included in the support member 20, are formed in one piece by die-casting using a metal material such as aluminum or an aluminum alloy, for example.

The base portion 21 is a rectangular plate-like member having an appropriate thickness. The circuit board assembly 10 is fixed to the support surface 211 of the base portion 21 by a known method such as gluing, screwing, or soldering.

The heat dissipation portion 22 includes a plurality of heat dissipation fins 221 that protrude downward from a lower side 212 of the base portion 21, and dissipates heat generated from the circuit board assembly 10 to the outside. The plurality of heat dissipation fins 221 extend in the left-right direction, and are provided in parallel with each other with gaps therebetween in the front-rear direction.

The leg portions 23 are provided at the left and right ends of the base portion 21. One or two or more leg portions 23 are provided at the respective left and right sides of the base portion 21.

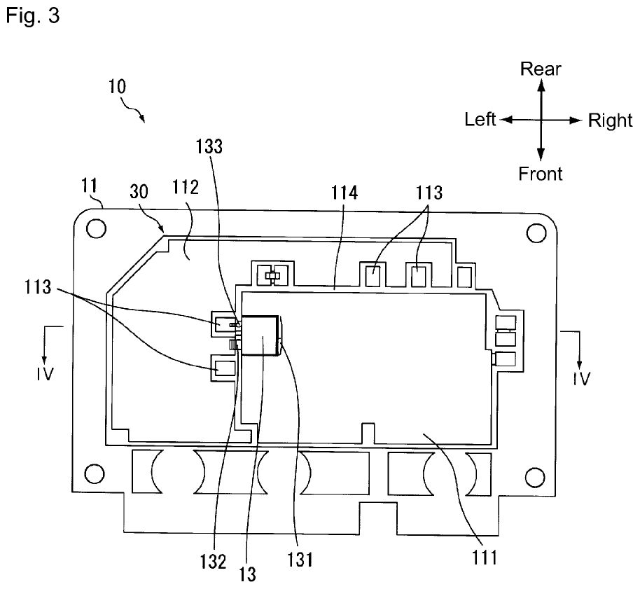

FIG. 3 is a schematic view of the circuit board assembly 10 of the electric apparatus 1 according to the first embodiment seen from below. In other words,

FIG. 3 is a diagram showing the circuit board assembly 10 seen in the direction of the arrow in FIG. 2.

The circuit board assembly 10 is provided with a power circuit 30, a circuit board 12 on which a control circuit that supplies an ON/OFF signal to the power circuit 30 is mounted, and a housing portion 11 that houses the power circuit 30 and the circuit board 12. The circuit board 12 and the power circuit 30 are provided separately from each other.

The power circuit 30 is provided with bus bars 111 to 113, a semiconductor switching element (component) 13 that receives the input of a control signal from the circuit board 12 and switches between a conductive state and a non-conductive state based on the input control signal.

The semiconductor switching element 13 is, for example, a FET (specifically, a surface-mounting type power MOSFET), and is mounted on the upper side of the bus bars 111 to 113. An electronic component such as a Zener diode may also be mounted in addition to the semiconductor switching element 13 (hereinafter referred to as a FET 13) on the upper sides of the bus bars 111 to 113.

Note that for illustrative reasons, a configuration in which only one FET 13 is mounted is shown in the example in FIG. 3, but of course a plurality of FETs 13 may also be mounted.

The FET 13 is provided with a drain terminal 131 on the right side surface of its element body, and a source terminal 132 and a gate terminal 133 on the left side surface of the element body. The drain terminal 131 of the FET 13 is connected by soldering to a bus bar 111 (hereinafter referred to as a drain bus bar 111) arranged in a region that occupies a large portion of the right part of the region exposed on the lower side of the circuit board assembly 10. Furthermore, the source terminal 132 of the FET 13 is connected by soldering to a bus bar 112 (hereinafter referred to as a source bus bar 112) arranged in a region that occupies a large portion of the left part and the rear part of the region exposed on the lower side of the circuit board assembly 10. These drain bus bar 111 and the source bus bar 112 are conductive plate members formed by a metal material such as copper or a copper alloy, and have a thickness of about 1.5 to 2.0 mm, for example.

On the other hand, the gate terminal 133 of the FET 13 is connected by soldering to the rectangular bus bar 113 (hereinafter referred to as the gate bus bar 113) arranged between and spaced apart from the drain bus bar 111 and the source bus bar 112, for example. The gate bus bar 113 is a conductive plate member formed by a metal material such as copper or a copper alloy, and have a thickness of about 0.64 mm, for example.

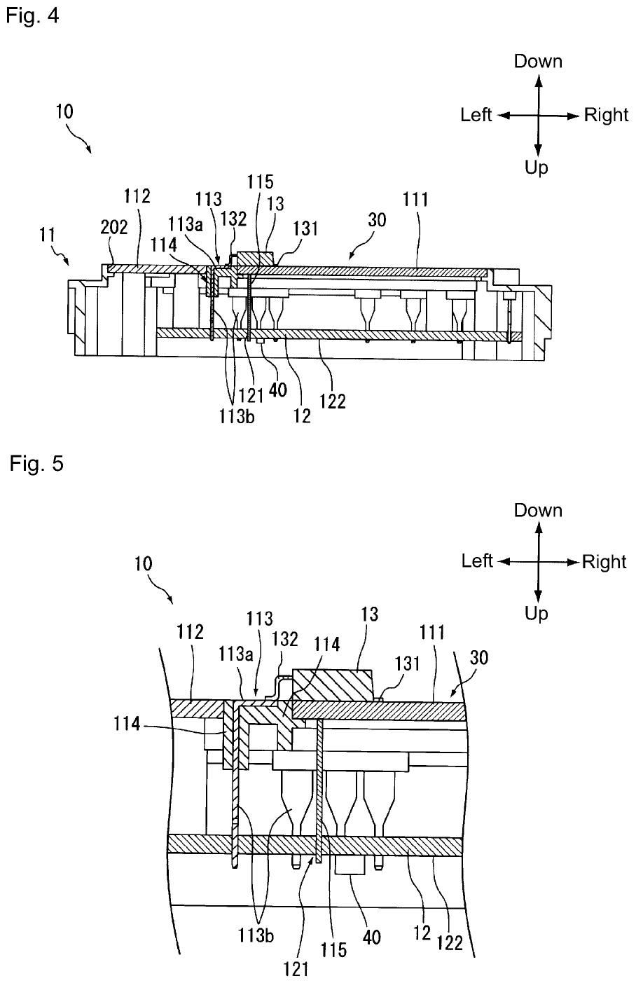

FIG. 4 is a vertical cross-sectional view taken along line IV-IV in FIG. 3.

Unlike the drain bus bar 111 and the source bus bar 112, the gate bus bar 113 is exposed on the lower side of the circuit board assembly 10, and the length in the up-down direction of a terminal connection portion 113a that is connected to the gate terminal 133 and a circuit board connection portion 113b that extends upward (on the circuit board 12 side) from one end of the terminal connection portion 113a may be designed as appropriate in accordance with the specification of the circuit board assembly 10 or the required heat resistance performance and the like.

The drain bus bar 111, the source bus bar 112, and the gate bus bar 113 are formed on the lower side of a resin molded body 114. In other words, the drain bus bar 111, the source bus bar 112, and the gate bus bar 113 are formed in one piece with the resin molded body 114 that is made of an insulating resin material, and form a housing portion 11.

The resin molded body 114 is manufactured by, for example, insert molding using an insulating resin material such as phenol resin, glass epoxy resin, or the like. The resin molded body 114 is a case made of a resin having openings on the upper end side and the lower end side.

The resin molded body 114 engages with the bus bars 111 to 113, thereby forming these bus bars into one piece. Portions of the resin molded body 114 are respectively arranged between the bus bars 111 to 113, thereby insulating the bus bars from each other. Furthermore, the resin molded body 114 supports a circumferential edge portion of the circuit board 12 from the lower side by a rib formed on the inner circumferential surface of the circumferential wall, thereby housing the circuit board 12 inside of the resin molded body 114.

The circuit board 12 includes an approximately rectangular-shaped insulating circuit board, for example. On the upper side 122 of this insulating circuit board, a control circuit (not shown) including electronic components such as a resistor, a coil, a capacitor, and a diode are mounted, and a circuit pattern that electrically connects these electronic components is formed.

Furthermore, a thermistor (sensor) 40 that detects heat (temperature) generated by the FET 13 of the power circuit 30 is mounted on the upper side 122 of the circuit board 12 (see FIGS. 4 and 5), and the control circuit controls the power circuit 30 based on the result of the detection by the thermistor 40.

In other words, since the FET 13 generates heat when a current flows therethrough, there is a risk of breakdown. Accordingly, the temperature of the heat generated by the FET 13 is detected using the thermistor 40. Since the resistance value of thermistor 40 varies depending on the temperature, the control circuit monitors the resistance value of the thermistor 40, and if it is determined that the temperature of the FET 13 is greater than or equal to the threshold, the control circuit outputs a control signal for turning OFF the power circuit 30, for example.

In the present embodiment, the thickness of the source bus bar 112 and the drain bus bar 111 is greater than that of the gate bus bar 113. By doing so, it is possible to accommodate a large current flowing between the power supply such as a battery mounted in a vehicle and loads including in-vehicle electrical components such as a lamp and a wiper or a motor and the like.

On the other hand, as described above, since the FET 13 generates heat when a current flows therethrough, if a large current flows through the FET 13, there is a risk that the FET 13 will generate excessive heat and break down. In order to prevent such a breakdown of the FET 13, in the circuit board assembly 10 according to the present embodiment, as described above, the circuit board 12 is provided with the thermistor 40 to monitor the temperature of the FET 13.

However, since the power circuit 30 on which the FET 13 is mounted and the circuit board 12 on which the thermistor 40 is mounted are provided separately from each other (see FIGS. 4 and 5), heat (temperature) of the FET 13 may not be accurately detected by the thermistor 40.

The circuit board assembly 10 according to the present embodiment is configured to solve this kind of problem. This will be described in detail below.

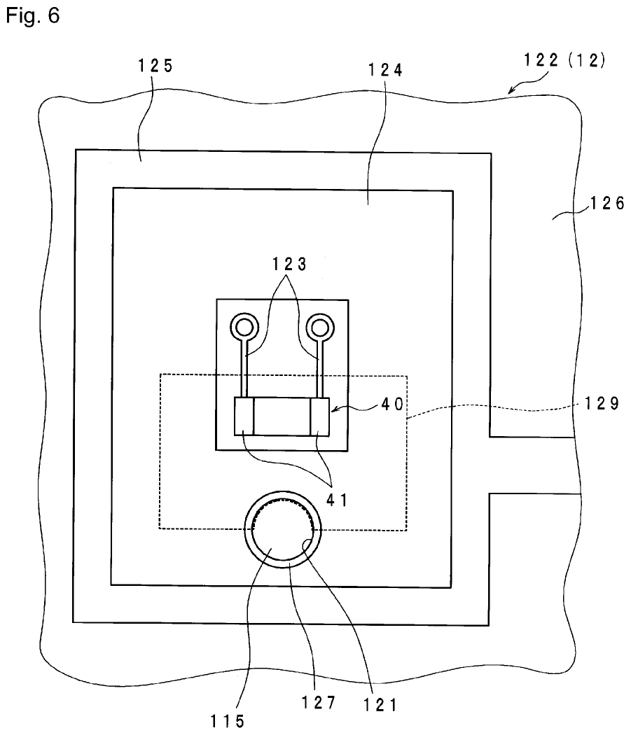

FIG. 6 is a partial schematic view of the circuit board 12 of the circuit board assembly 10 according to the first embodiment seen from above. FIG. 6 shows the region of the thermistor 40 on the upper side 122 of the circuit board 12.

The thermistor 40 is shaped like a cuboid and includes terminals 41 at its two end portions in the longitudinal direction. The terminals 41 are connected by soldering to a wiring (circuit pattern) 123 formed on the upper side 122 of the circuit board 12.

The thermistor 40 (and the wiring 123) is surrounded by a heat conductive pattern 124. The heat conductive pattern 124 is made of a highly heat conductive material such as silver and copper, and shaped like a hollow rectangular film. In the present embodiment, the heat conductive pattern 124 is a copper film, for example, and formed by patterning processing as with a circuit pattern 126 (another pattern) that electrically connects the electronic components of the control circuit of the circuit board 12.

In the present embodiment, an example in which the heat conductive pattern 124 is electrically conductive has been described, but there is no limitation to this, and the material of the heat conductive pattern 124 need only be a material that is insulating and highly heat conductive. In this case, the heat conductive pattern 124 can be formed surrounding only the thermistor 40.

The heat conductive pattern 124 is a land portion separate from the circuit pattern 126. In other words, the heat conductive pattern 124 is not in contact with the circuit pattern 126, and a portion 125 of the insulating circuit board (hereinafter referred to as the insulating portion 125) is interposed between the heat conductive pattern 124 and the circuit pattern 126. Accordingly, the heat conductive pattern 124 is completely insulated from the circuit pattern 126.

A through hole 121 is formed near the thermistor 40 in the heat conductive pattern 124. As described above, the upper end of the heat conductive member 115 is inserted into the through hole 121, and the heat conductive pattern 124 and the heat conductive member 115 are joined to each other through a joining portion 127. The joining portion 127 is made of a highly heat conductive material.

A large portion of the FET 13 is arranged on the drain bus bar 111, and the drain bus bar 111 is in contact with the heat conductive member 115. Accordingly, heat generated by the FET 13 is conducted to the lower end of the heat conductive member 115 via the drain bus bar 111. In this manner, the heat conducted to the heat conductive member 115 is conducted to the heat conductive pattern 124 via the joining portion 127 on the upper end side of the heat conductive member 115. Subsequently, the heat spreads on the entire surface of the heat conductive pattern 124. Since the thermistor 40 is surrounded by the heat conductive pattern 124, heat generated by the FET 13 can be reliably detected.

With this configuration, with the circuit board assembly 10 according to the present embodiment, even if the power circuit 30 on which the FET 13 is mounted and the circuit board 12 on which the thermistor 40 that detects the temperature of the power circuit 30 (FET 13) is mounted are separate from each other, the thermistor 40 can reliably detect the temperature of the FET 13.

In addition, as described above, the heat conductive pattern 124 is spaced apart from the circuit pattern 126. Accordingly, the heat conducted to the heat conductive pattern 124 is not conducted to the circuit pattern 126, and cases in which the electronic components mounted on the circuit pattern 126 are adversely affected can be prevented.

As described above, since the circuit pattern 126 is formed around the heat conductive pattern 124, a case in which the insulating portion 125 surrounds the heat conductive pattern 124 has been described as an example. However, there is no limitation to this.

For example, the heat conductive pattern 124 may also be provided at the edge portion of the circuit board 12. Generally, the circuit pattern 126 is not formed at the edge portion of the circuit board. Accordingly, by forming the heat conductive pattern 124 (thermistor 40) at the edge portion of the circuit board 12, forming of the insulating portion 125 can be partially omitted, thereby minimizing the area occupied by the heat conductive pattern 124. For example, if a rectangular heat conductive pattern 124 is formed at a corner of the rectangular circuit board 12 so that the two sides of the heat conductive pattern 124 are in parallel with two sides of the circuit board 12, the insulating portion 125 need only be formed at the portions corresponding to the other two sides of the heat conductive pattern 124.

### Second Embodiment

In a circuit board assembly 10 according to the present embodiment, the heat conductive member 115 includes a single end portion on the lower side, and a plurality of end portions on the upper side. Hereinafter, for illustrative reasons, a case in which the heat conductive member 115 includes two upper end portions will be described as an example.

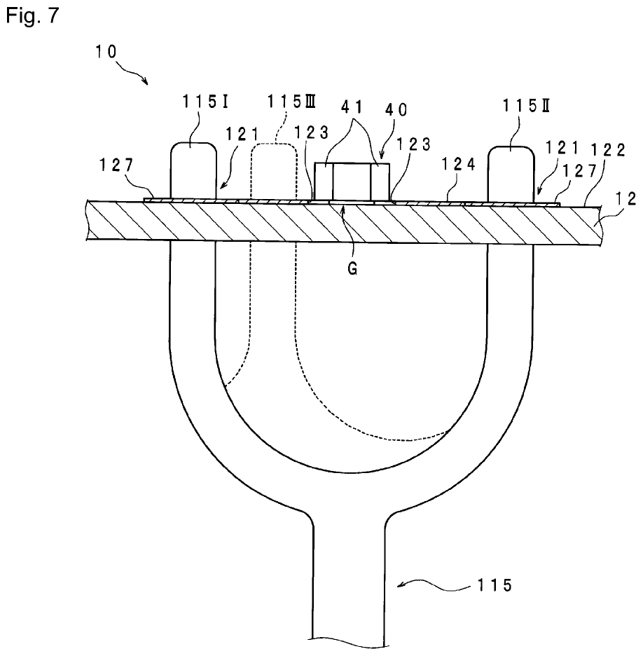

FIG. 7 is a vertical cross-sectional view showing a region of a thermistor 40 in the circuit board assembly 10 according to a second embodiment. The heat conductive member 115 includes an end portion 115I and an end portion 115II that are branched into a U-shape, on the upper side (circuit board 12 side).

Two through holes 121 are formed near the thermistor 40 in the heat conductive pattern 124. The end portion 115I and the end portion 115II are respectively inserted into the two through holes 121, and joined to the heat conductive pattern 124 through the joining portion 127. In this case, the thermistor 40 is surrounded by the end portion 115I and the end portion 115II. In other words, the thermistor 40 is arranged between the end portion 115I and the end portion 115II.

The circuit board assembly 10 according to the present embodiment is not limited to the above description. A configuration is also possible in which the upper end portion of the heat conductive member 115 includes three or more end portions. FIG. 7 illustrates a case in which the upper end portion of the heat conductive member 115 is formed by three parts. In other words, FIG. 7 illustrates a case in which the heat conductive member 115 includes an end portion 115III (dashed line in FIG. 7) in addition to the end portion 115I and the end portion 115II.

In this manner, also in the case in which the upper end portion of the heat conductive member 115 is formed by three or more parts, the thermistor 40 is arranged at a location surrounded by the plurality of parts. In FIG. 7, for example, the thermistor 40 is located in the center of a triangle formed by the end portions 115I, 115II, and 115III.

Heat generated by the FET 13 is conducted to the lower end of the heat conductive member 115 via the drain bus bar 111. In this manner, the heat conducted to the heat conductive member 115 is conducted to the heat conductive pattern 124 via the joining portions 127 of the end portion 115I and the end portion 115II (and the end portion 115III). Subsequently, heat spreads on the entire surface of the heat conductive pattern 124 more rapidly than in cases in which the heat conductive member 115 has a single end portion. Since the thermistor 40 is surrounded by the heat conductive pattern 124, heat generated by the FET 13 can be reliably detected.

With this configuration, in the circuit board assembly 10 according to the present embodiment, even if the power circuit 30 on which the FET 13 is mounted and the circuit board 12 on which the thermistor 40 that detects the temperature of the power circuit 30 (FET 13) is mounted are separate from each other, the thermistor 40 can detect the temperature of the FET 13 more quickly and more reliably.

The parts similar to the first embodiment are given the same reference numerals and the description thereof is omitted.

### Third Embodiment

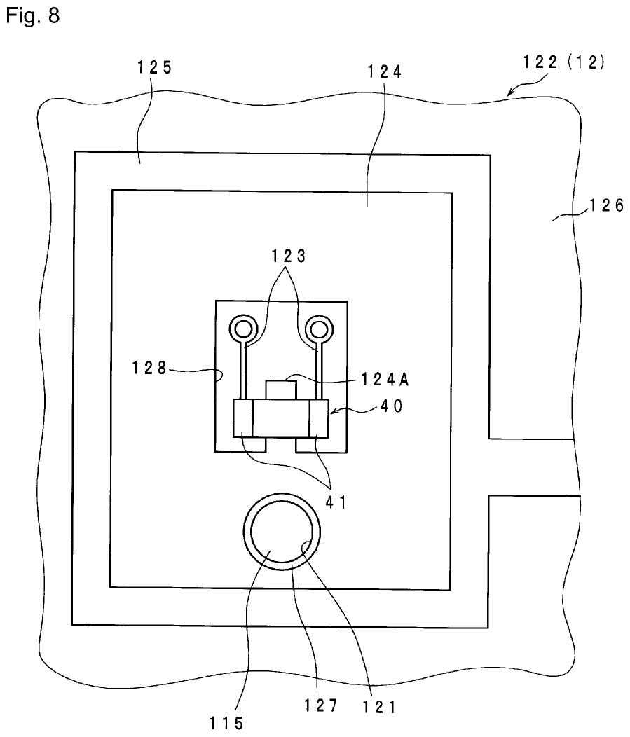

FIG. 8 is a partial schematic view of a circuit board 12 of a circuit board assembly 10 according to a third embodiment seen from above. FIG. 8 shows the region of the thermistor 40 on the upper side 122 of the circuit board 12.

As described above, the thermistor 40 includes terminals 41 at the two end portions in the longitudinal direction and the terminals 41 are connected by soldering to the wiring 123 formed on the upper side 122 of the circuit board 12. In other words, since only the two ends in the longitudinal direction of the thermistor 40 are connected to the wiring 123 (upper side 122 of the circuit board 12), a gap G (see FIG. 7) is present between the portion excluding the two ends in the longitudinal direction (in particular, the center in the longitudinal direction) and the upper side 122.

In the present embodiment, a portion of the heat conductive pattern 124 is formed in the gap G.

The heat conductive pattern 124 is shaped in a hollow rectangle, and surrounds the thermistor 40 in a square shape. In other words, a void portion 128 at which the heat conductive pattern 124 is not formed is present near the thermistor 40 and the wiring 123 in the heat conductive pattern 124. The void portion 128 is approximately shaped like a rectangle, and the upper side 122 of the circuit board 12 is exposed therefrom.

The heat conductive pattern 124 includes an extending portion 124A that extends along the upper side 122 of the circuit board 12 from the edge of the void portion 128. The extending portion 124A is a strip-like film, and extends toward the center portion of the void portion 128 through the gap G between the thermistor 40 and the upper side 122 of the circuit board 12.

Heat generated by the FET 13 is conducted to the lower end of the heat conductive member 115 via the drain bus bar 111, and then conducted from the upper end of the heat conductive member 115 to the thermistor 40 in its vicinity by radiation.

Furthermore, the heat conducted to the heat conductive member 115 is conducted to the heat conductive pattern 124 via the joining portion 127 on the upper end side of the heat conductive member 115. Subsequently, the heat spreads on the entire surface of the heat conductive pattern 124 including the extending portion 124A. The thermistor 40 is surrounded by the heat conductive pattern 124, and the extending portion 124A of the heat conductive pattern 124 is formed directly below the thermistor 40. Accordingly, the thermistor 40 can reliably detect the heat generated by the FET 13.

With this configuration, in the circuit board assembly 10 according to the present embodiment, even if the power circuit 30 on which the FET 13 is mounted and the circuit board 12 on which the thermistor 40 that detects the temperature of the power circuit 30 (FET 13) is mounted are separate from each other, the thermistor 40 can detect the temperature of the FET 13 more reliably.

The parts similar to the first embodiment are given the same reference numerals and the description thereof is omitted.

### Fourth Embodiment

In a circuit board assembly 10 according to the present embodiment, the circuit board 12 is constituted by multiple layers. In the description below, a case in which the circuit board 12 is formed by three layers will be described as an example.

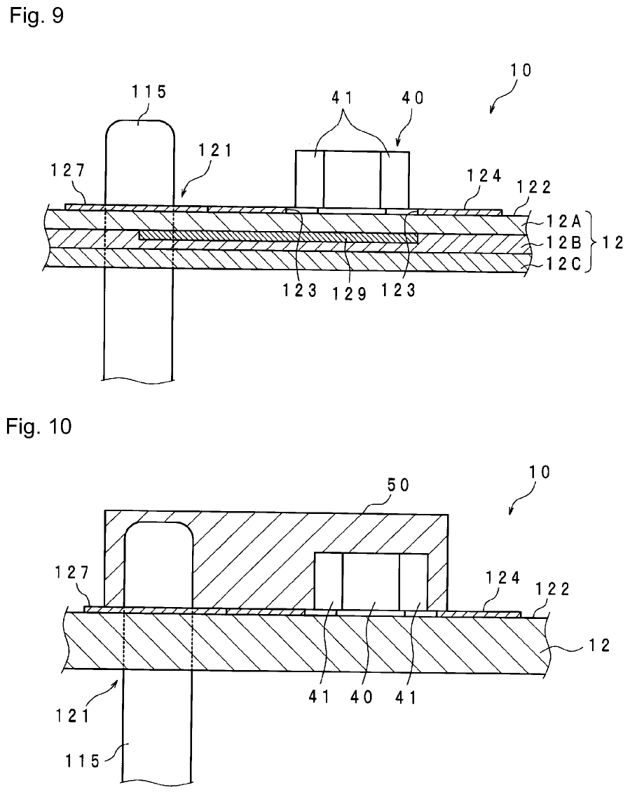

FIG. 9 is a vertical cross-sectional view showing a region of a thermistor 40 in the circuit board assembly 10 according to a fourth embodiment.

The circuit board 12 includes a first layer 12A (mounting layer) on the upper side 122 on which the thermistor 40 is mounted, a third layer 12C on the lower side opposite to the upper side 122, and a second layer 12B interposed between the first layer 12A and the third layer 12C.

The second layer 12B includes an internal heat conductive pattern 129. In other words, the internal heat conductive pattern 129 is provided inside the circuit board 12. The internal heat conductive pattern 129 includes a location corresponding to the thermistor 40 in the thickness direction, i.e., the up-down direction of the circuit board 12. Furthermore, the internal heat conductive pattern 129 is formed in a range that is larger than the thermistor 40 in the left-right direction and the front-rear direction that intersect the up-down direction. The region occupied by the internal heat conductive pattern 129 is indicated by the dashed line in FIG. 6. The internal heat conductive pattern 129 is made of a highly heat conductive material such as silver and copper, and is shaped like a film.

Furthermore, as seen from FIG. 6 and FIG. 9, the internal heat conductive pattern 129 is configured to be in contact with the heat conductive member 115.

Heat generated by the FET 13 is conducted to the lower end of the heat conductive member 115 via the drain bus bar 111, and the heat conducted to the heat conductive member 115 is then conducted to the heat conductive pattern 124 via the joining portion 127 on the upper end side of the heat conductive member 115. Subsequently, the heat spreads on the entire surface of the heat conductive pattern 124. The thermistor 40 is surrounded by the heat conductive pattern 124, and thus the thermistor 40 can reliably detect the heat generated by the FET 13.

At this time, the heat conducted to the heat conductive member 115 is also conducted to the internal heat conductive pattern 129 of the second layer 12B via the heat conductive member 115. Subsequently, the heat spreads on the entire surface of the internal heat conductive pattern 129, and is conducted to the thermistor 40 via the first layer 12A.

With this configuration, with the circuit board assembly 10 according to the present embodiment, even if the power circuit 30 on which the FET 13 is mounted and the circuit board 12 on which the thermistor 40 that detects the temperature of the power circuit 30 (FET 13) is mounted are separate from each other, the thermistor 40 can detect the temperature of the FET 13 more reliably.

The parts similar to the first embodiment are given the same reference numerals and the description thereof is omitted.

### Fifth Embodiment

A circuit board assembly 10 according to the present embodiment is configured so that heat of the heat conductive member 115 can be directly conducted to the thermistor 40.

FIG. 10 is a vertical cross-sectional view showing a region of a thermistor 40 in the circuit board assembly 10 according to a fifth embodiment.

The circuit board assembly 10 according to the present embodiment includes a conducting member 50 that directly conducts heat of the heat conductive member 115 to the thermistor 40. The conducting member 50 is provided in contact with the heat conductive member 115 and the thermistor 40. To be more specific, the conducting member 50 covers the upper end portions of the heat conductive member 115 while being in contact with the almost entire surface of the upper end portions of the heat conductive member 115. Also, the conducting member 50 covers the thermistor 40 while being in contact with the surface of the thermistor 40 excluding the lower side. Accordingly, heat of the heat conductive member 115 can be directly conducted to the thermistor 40.

Furthermore, the conducting member 50 is provided partially in contact with the heat conductive pattern 124 as well. Accordingly, the conducting member 50 can also directly conduct heat of the heat conductive member 115 to the heat conductive pattern 124.

The conducting member 50 is made of a highly heat conductive insulating material. The conducting member 50 may also be made of a gel-like material such as grease, or a solid such as a heat-conducting sheet or alumite.

Heat generated by the FET 13 is conducted to the lower end of the heat conductive member 115 via the drain bus bar 111. The heat conducted to the heat conductive member 115 is conducted to the heat conductive pattern 124 via the joining portion 127 on the upper end side of the heat conductive member 115.

Subsequently, the heat spreads on the entire surface of the heat conductive pattern 124. The thermistor 40 is surrounded by the heat conductive pattern 124, and thus the thermistor 40 can reliably detect the heat generated by the FET 13.

The heat conducted to the heat conductive member 115 is directly conducted from the heat conductive member 115 to the thermistor 40 via the conducting member 50. Furthermore, the heat conducted to the heat conductive member 115 is also directly conducted to the heat conductive pattern 124 via the conducting member 50, and spreads on the entire surface of the heat conductive pattern 124.

With this configuration, with the circuit board assembly 10 according to the present embodiment, even if the power circuit 30 on which the FET 13 is mounted and the circuit board 12 on which the thermistor 40 that detects the temperature of the power circuit 30 (FET 13) is mounted are separate from each other, the thermistor 40 can reliably detect the temperature of the FET 13.

The parts similar to the first embodiment are given the same reference numerals and the description thereof is omitted.

The embodiments disclosed herein are to be considered illustrative and non-limiting in all aspects. The scope of the present disclosure is defined not by the above descriptions but by the claims, and intended to encompass all the modifications within the meanings and scope of the equivalents of the claims.

1. A circuit board assembly comprising:
an electronic component that generates heat;
a sensor that is mounted on a circuit board that is spaced apart from the electronic component, the sensor being configured to detect a temperature of the electronic component;
a heat conductive pattern that is formed surrounding the sensor; and
a heat conductive member that conducts heat from the electronic component to the heat conductive pattern.

2. The circuit board assembly according to claim 1,
wherein another pattern is formed on the circuit board, and
the heat conductive pattern is a land portion that is spaced apart from the other pattern.

3. The circuit board assembly according to claim 1, wherein the heat conductive member comprises, on the circuit board side, a plurality of end portions that surround the sensor.

4. The circuit board assembly according to claim 1, wherein a gap is present partially between the sensor and the circuit board, and
a portion of the heat conductive pattern is formed in the gap.

5. The circuit board assembly according to claim 1, wherein the circuit board is constituted by a plurality of layers, and
the circuit board includes an internal heat conductive pattern formed in contact with the heat conductive member at a location corresponding to the sensor in a thickness direction of the circuit board in another layer than a layer on which the sensor is mounted.

6. The circuit board assembly according to claim 1, further comprising:
a conducting member that conducts heat of the heat conductive member to the sensor.

7. The circuit board assembly according to claim 2, wherein the heat conductive member comprises, on the circuit board side, a plurality of end portions that surround the sensor.

8. The circuit board assembly according to claim 2, wherein a gap is present partially between the sensor and the circuit board, and
a portion of the heat conductive pattern is formed in the gap.

9. The circuit board assembly according to claim 2, wherein the circuit board is constituted by a plurality of layers, and
the circuit board includes an internal heat conductive pattern formed in contact with the heat conductive member at a location corresponding to the sensor in a thickness direction of the circuit board in another layer than a layer on which the sensor is mounted.

10. The circuit board assembly according to claim 2, further comprising:
a conducting member that conducts heat of the heat conductive member to the sensor.
